(19) United States
(12) Patent Application Publication
(10) Pub. No.: US 2023/0184546 A1
(43) Pub. Date: Jun. 15, 2023

(54) APPARATUS AND METHOD FOR MEASURING OVERLAY

(71) Applicant: AUROS TECHNOLOGY, INC., Hwaseong-si (KR)

(72) Inventors: Seung Soo LEE, Osan-si (KR); Jun Hyeok BAEK, Uiwang-si (KR); Young Je WOO, Seoul (KR)

(21) Appl. No.: 18/168,134

(22) Filed: Feb. 13, 2023

Related U.S. Application Data
(63) Continuation-in-part of application No. 17/292,994, filed on May 11, 2021.

(30) Foreign Application Priority Data
Sep. 14, 2018 (KR) 10-2018-0110421

(51) Int. Cl. G01B 11/27; G01B 11/06; H01L 21/68

(52) U.S. Cl. CPC G01B 11/27; G01B 11/0608; H01L 21/681

(57) ABSTRACT

An apparatus, for measuring overlay, includes: a height difference detection optical system detecting a height difference between a first overlay mark and a second overlay mark; an illumination optical system irradiating the overlay mark with illumination light; a main beam splitter splitting a reflected light from the overlay mark into a first beam and a second beam; a first detector receiving the first beam and generating a first overlay mark image in which the first overlay mark is displayed; a second detector receiving the second beam and generating a second overlay mark image in which the second overlay mark is displayed; an imaging optical system allowing the first beam to be imaged on the first detector; and a telecentric imaging optical system adjusting a length of an optical path of the second beam to allow the second beam to be imaged on the second detector.

### BACKGROUND OF THE INVENTION

### Field of the Invention

The disclosed embodiments of the invention relates to an apparatus and method for measuring overlay.

### Description of the Related Art

As technology develops, it is required that the size of semiconductor devices is reduced and the density of integrated circuits is increased. In order to meet these requirements, various conditions must be satisfied, and overlay tolerance among them is an important indicator.

Semiconductor devices are manufactured through numerous manufacturing processes. In order to form an integrated circuit on a wafer, many manufacturing processes are required to sequentially form desired circuit structures and elements at specific locations. The fabrication process allows for the sequential creation of patterned layers on a wafer. These repeated lamination processes create electrically active patterns in integrated circuits. Herein, when each lamination structure is not within the tolerance range, which is allowable in the manufacturing process, interference occurs between the electrically active patterns, which results in degrading the performance and utilization of manufactured circuits. An overlay measurement tool is used to measure and verify such inter-layer alignment errors.

In general, it is verified that the alignment between two layers is within tolerance error using the overlay measuring methods. Among such methods, there is a method of measuring overlay by forming a structure called an overlay mark at a specific location on a substrate and photographing the structure with an optical image acquisition device. The structure is provided to measure the overlay in at least one of X and Y directions for each layer. Since each structure is designed as a symmetrical structure, the center value between the structures arranged in the symmetrical direction is calculated. Then, an overlay error may be derived by calculating a relative difference between representative values of each layer using the center value as the representative value of the layer.

In the case of measuring the overlay in two layers, as shown in FIGS. 1 and 2, an outer box 1 and an inner box 2 smaller than the outer box 1 are formed on two consecutive layers, respectively. Then, as shown in FIGS. 3 and 4, a central value C1 of the outer box 1 is obtained by obtaining a waveform representing a change in intensity for each position after making focus on the outer box 1, and a central value C2 of the inner box 2 is obtained by obtaining a waveform representing a change in intensity for each position after making focus on the inner box 2, resulting in measuring the overlay error between the two consecutive layers.

However, according to the conventional method, in the case that a height difference between the layer on which the outer box 1 is formed and the layer on which the inner box 2 is large, when the focus is made on one of the outer box 1 and the inner box 2, the focus is not made on the other, whereby there is a problem of blurring.

In addition, a problem is caused since the waveform or image of the outer box 1 and the inner box 2 are acquired using the same beam, without considering facts that the outer box 1 and the inner box 2 are made of different materials on different layers, and the outer box 1 is covered by the layer on which the child layer 2 is formed.

Currently, there is a growing need for accurately and rapidly measuring overlay errors between layers which have a large height difference and different optical properties due to the development of semiconductor process technology.

### DOCUMENTS OF RELATED ART

(Patent Document 0001) Korean Patent Publication No. 2003-0054781

(Patent Document 0002) Korean Patent No. 10-0689709

(Patent Document 0003) Korean Patent No. 10-1564312

(Patent Document 0004) Korean Patent Publication No. 10-2018-0042649

(Patent Document 0005) Korean Patent Publication No. 10-2018-0045026

(Patent Document 0006) Japan Patent Publication No. 2005-519460

(Patent Document 0007) Korean Patent No. 10-2120551

### SUMMARY OF THE INVENTION

Accordingly, the present invention has been made keeping in mind the above problems occurring in the conventional art, and an objective of the present invention is to provide an apparatus and method for measuring overlay, which is capable of accurately and rapidly measuring an overlay error between layers having a large height difference and different optical properties.

In order to achieve the above objective, embodiments of the invention provides an apparatus for measuring overlay, which is configured to measure an inter-layer overlay error in a sample with an overlay mark being formed, the overlay mark including a first overlay mark and a second overlay mark respectively formed on different layers. The apparatus includes: a height difference detection optical system detecting a height difference (Δh) between the first overlay mark and the second overlay mark; an illumination optical system irradiating the overlay mark on the sample with illumination light; a main beam splitter splitting the light reflected from the overlay mark into a first beam and a second beam; a first detector receiving the first beam and generating a first overlay mark image in which the first overlay mark is clearly displayed; a second detector receiving the second beam and generating a second overlay mark image in which the second overlay mark is clearly displayed; an imaging optical system allowing the first beam to be imaged on the first detector; and a telecentric imaging optical system including an optical path adjusting unit for adjusting a length of an optical path of the second beam based on the height difference (Δh), and a telecentric lens disposed between the main beam splitter and the second detector to allow the second beam to be imaged on the second detector.

In addition, the optical path adjusting unit may include at least one mirror disposed between the beam splitter and the second detector to cause the second beam to be reflected toward the second detector; a mirror stage configured to adjust a length of an optical path of the second beam by linearly moving the mirror; and a controller for controlling the mirror stage based on the height difference (Δh).

In addition, the controller may control the mirror stage so that the optical path of the second beam is lengthened by considering the product of the height difference (Δh) and the magnification of the second overlay mark image, and the lengthened optical path of the second beam becomes longer than an optical path of the first beam.

In addition, the imaging optical system may further include a first optical filter which is disposed in front of the first detector to adjust a central wavelength and a band width of the first beam for obtaining the first overlay mark image, and the telecentric imaging optical system may further include a second optical filter which is disposed in front of the second detector to adjust a central wavelength and a band width of the second beam for obtaining the second overlay mark image.

In addition, the first optical filter and the second optical filter may be linear variable filters or rotational variable filters.

In addition, the first detector and the second detector may be synchronized so that the first overlay mark image and the second overlay mark image are generated simultaneously.

Embodiments of the invention also provide a method of measuring overlay, which is to measure an inter-layer overlay error in a sample with an overlay mark being formed, the overlay mark including a first overlay mark and a second overlay mark respectively formed on different layers. The method includes: detecting a height difference (Δh) between the first overlay mark and the second overlay mark; irradiating the overlay mark on the sample with illumination light; splitting the light reflected from the overlay mark into a first beam and a second beam; allowing the first beam to be imaged on a first detector; adjusting the length of the optical path of the second beam based on the height difference (Δh) so that the focus is made on the second overlay mark; allowing the second beam to be imaged on a second detector, the second beam passing through a telecentric lens and an optical path of which length is adjusted; generating, from the first detector, a first overlay mark image with the first overlay mark being clearly displayed, and generating, from the second detector, a second overlay mark image with the second overlay mark being clearly displayed.

In addition, the length of the optical path of the second beam may be adjusted so that the optical path of the second beam is lengthened by considering the product of the height difference (Δh) and the magnification of the second overlay mark image, and the lengthened optical path of the second beam becomes longer than an optical path of the first beam.

In addition, the method may further include adjusting a central wavelength and a band width of the first beam for acquiring the first overlay mark image; and adjusting a central wavelength and a band width of the second beam for acquiring the second overlay mark image.

In addition, the central wavelength of the first beam and the central wavelength of the second beam may be different from each other.

In addition, the first detector and the second detector may be synchronized so that the first overlay mark image and the second overlay mark image are generated simultaneously.

The overlay measurement apparatus and method according to embodiments of the invention has the advantage of being able to accurately and rapidly measure the overlay error between layers having a large height difference and different optical properties.

### BRIEF DESCRIPTION OF THE DRAWINGS

The above and other objects, features, and other advantages of the invention will be more clearly understood from the following detailed description of the embodiments when taken in conjunction with the accompanying drawings, in which:

FIG. 1 is a top view illustrating overlay marks;

FIG. 2 is a side view illustrating the overlay marks shown in FIG. 1;

FIG. 3 shows waveforms of changes in intensity for each position of a signal obtained in a state of making focus on the parent ruler of the overlay marks shown in FIG. 1;

FIG. 4 shows waveforms of changes in intensity for each position of a signal obtained in a state of making focus on the child ruler of the overlay mark shown in FIG. 1;

FIG. 5 is a conceptual diagram illustrating an apparatus for measuring overlay, according to an exemplary embodiment.

FIG. 6 is a diagram illustrating the intensity according to the wavelength of the first illumination light passing through the first color filter shown in FIG. 5;

FIG. 7 is a diagram illustrating the intensity according to a wavelength of second illumination light passing through the second color filter shown in FIG. 5;

FIG. 8 is a diagram illustrating the intensity according to the wavelength of illumination light passing through the beam combiner shown in FIG. 5;

FIG. 9 is an exemplary view illustrating a method of irradiating a first overlay mark and a second overlay mark formed on a sample with illumination light;

FIG. 10 is a diagram illustrating a first overlay mark image acquired from the first detector shown in FIG. 5;

FIG. 11 is a diagram illustrating a second overlay mark image acquired from the second detector shown in FIG. 5;

FIG. 12 is a diagram illustrating an image obtained by combining a first overlay mark image and a second overlay mark image; and

FIG. 13 is a flowchart illustrating a method of measuring overlay, according to an exemplary embodiment.

### DETAILED DESCRIPTION OF THE EMBODIMENTS

Hereinafter, one embodiment of the invention will be described in detail with reference to the accompanying drawings. However, embodiments of the invention may be modified in many different forms, and the scope of the invention should not be construed as being limited to the embodiments described below. Embodiments of the invention are provided to more completely explain the invention to a person of ordinary skill in the art. Therefore, the shapes of elements in the drawings may be exaggerated to emphasize a clearer explanation, and elements indicated by the same reference numerals in the drawings may mean the same elements.

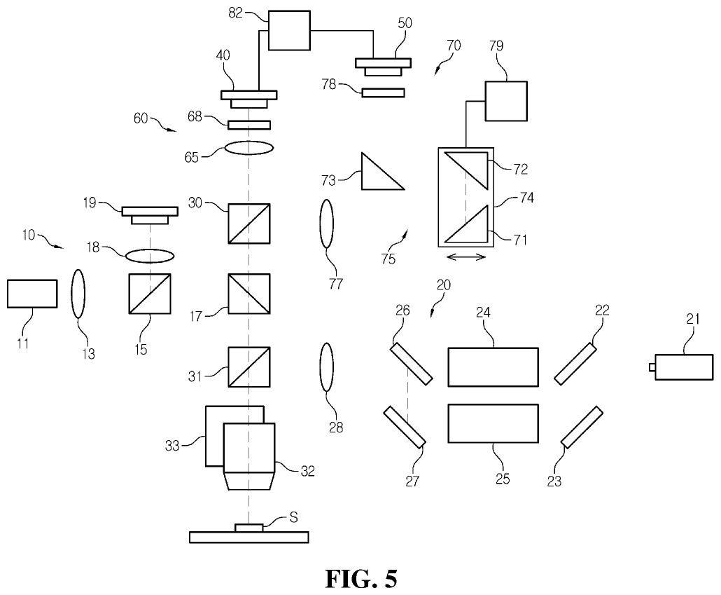

FIG. 5 is a conceptual diagram illustrating an apparatus for measuring overlay, according to an embodiment. The apparatus for measuring overlay is to measure an overlay error between different layers by measuring an error between a first overlay mark OM1 and a second overlay mark OM2 respectively formed on different layers of a sample such as a semiconductor wafer.

For example, as shown in FIG. 9, the second overlay mark OM2 is an overlay mark formed on the previous layer, the first overlay mark OM1 may be an overlay mark formed on the current layer. The overlay marks are formed on a scribe lane simultaneously when a layer for forming a semiconductor device is formed in a die region of a semiconductor wafer. For example, the second overlay mark OM2 is formed together with the insulating film pattern, and the first overlay mark OM1 may be formed with a photoresist pattern formed on the insulating layer pattern.

Herein, while the first overlay mark OM1 is exposed to the outside, the second overlay mark OM2 is in a state covered by the photoresist layer and is made of an oxide having an optical property different from that of the first overlay mark OM1 made of a photoresist material. In addition, the focal planes of the first overlay mark OM1 and the second overlay mark OM2 are different from each other.

According to an exemplary embodiment, a first overlay mark image I1 is obtained by using a beam suitable for optical properties of a material constituting the first overlay mark OM1 in the state of making focus on the first overlay mark OM1. Similarly, a second overlay mark image I2 is obtained by using a beam suitable for optical properties of a material constituting the second overlay mark OM2 in the state of making focus on the second overlay mark OM2. Then, using the first overlay mark image I1 and the second overlay mark image I2 enables the overlay error to be accurately and rapidly measured.

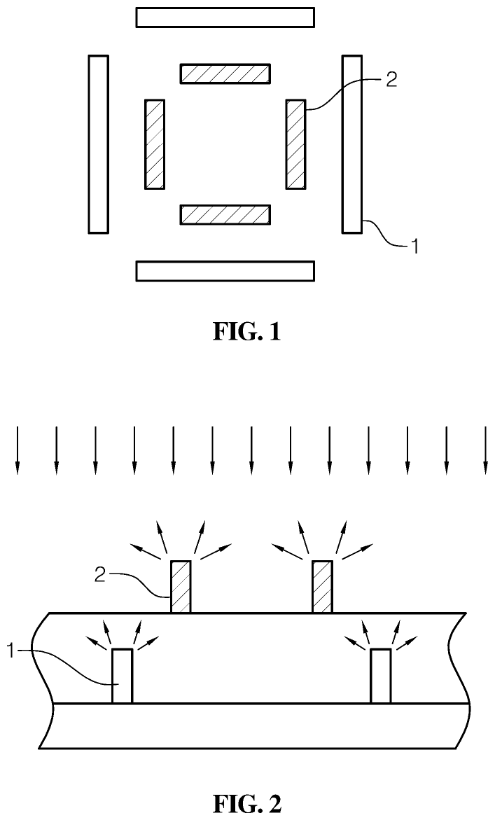

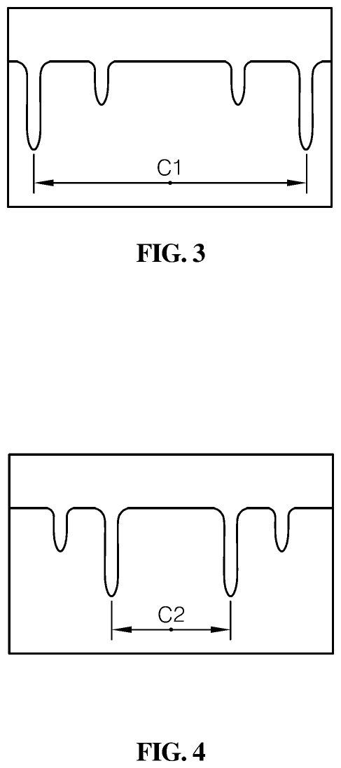

The overlay mark may be various overlay marks, which are currently used, such as a box-in-box (BIB, see FIG. 1), an advanced imaging metrology (AIM) overlay mark, and the like. Hereinafter, the box-in-box overlay mark will be mainly described as an example, of which the structure is simple.

As shown in FIG. 5, an overlay measuring device, according to an exemplary embodiment, includes a height difference detection optical system 10, an illumination optical system 20, a main beam splitter 30, a first detector 40, and a second detector 50, an imaging optical system 60, and a telecentric imaging optical system 70.

The height difference detection optical system 10 is to measure a height difference Δh between the first overlay mark OM1 and the second overlay mark OM2. The height difference detection optical system 10 may be configured with various optical elements. The height difference detection optical system 10 may also be used as an autofocusing optical system.

For example, as shown in FIG. 5, the height difference detection optical system 10 may include a light source 11, a collimation lens 13 that makes parallel a beam from the light source 11, and a beam splitter 15, and an image sensor 19. The height difference detection optical system 10 may further include a hot mirror 17, a beam splitter 31, and an objective lens 32, which are commonly used for the imaging optical system 60, the illumination optical system 40, and the telecentric imaging optical system 70.

As the light source 11, a laser diode or a light emitting diode may be used. The light source 11 may generate light in an infrared wavelength band.

The light generated from the light source 11 passes through the collimator 13 and the beam splitter 15. When a laser is used as the light source 11, for example, a polarization beam splitter may be used as the beam splitter 15, because it is possible to avoid a decrease in an amount of light in the process of reflection and transmission.

The hot mirror 17 is to reflect the light belonging to an infrared wavelength band. The light reflected from the hot mirror 17 passes through the beam splitter 31 and then enters the objective lens 32.

The objective lens 32 serves to condense light to a measurement location on the surface of the sample S and collect reflected light reflected from the measurement location. The reflected light collected by the objective lens 32 passes through the beam splitter 31 back and then is reflected by the hot mirror 17. The reflected light reflected from the hot mirror 17 is reflected from the beam splitter 15 toward the image sensor 19 and then focused on the image sensor 19 by the focusing lens 18. Since light belonging to the infrared wavelength band does not pass through the hot mirror 17, the light used to measure the height difference does not enter the first detector 40.

The image sensor 19 receives reflected light from the sample S. Here, the image sensor 19 may be a CCD sensor or a CMOS sensor. By analyzing contrast of the image from the image sensor 19, it may be determined whether the focus is made. Therefore, when analyzing the optical signal from the detector 19 according to the distance between the objective lens 32 and the sample S, it is possible to find the position of the objective lens 32 when making focus on the first overlay mark OM1 and the position of the objective lens 32 when making focus on the second overlay mark OM2. Then, comparing these positions results in finding the height difference Δh between the first overlay mark OM1 and the second overlay mark OM2.

The illumination optical system 20 serves to illuminate the overlay mark. The illumination optical system may be configured using various optical elements. For example, as shown in FIG. 5, the illumination optical system 20 includes an illumination source 21, a beam splitter 22, a first color filter 24, a second color filter 25, mirrors 23 and 27, and a beam combiner 26, and an objective lens 32.

The illumination source 21 generates light in a wide wavelength band. As the illumination source 21, a halogen lamp, a xenon lamp, a supercontinuum laser, a light emitting diode, a laser induced lamp, or the like may be used.

The beam splitter 22 is to split the light beam from the illumination source 21 into two beams. That is, the beam splitter 22 transmits a portion of the beam from the illumination source 21 and reflects a portion of the beam, thereby splitting the light beam from the illumination source 21 into two beams.

The first color filter 24 is to adjust the central wavelength and band width of the beam transmitted through the beam splitter 22 among the beams split by the beam splitter 22 to be suitable for detection of the first overlay mark OM1 formed on the current layer. For example, the central wavelength may be adjusted so that the reflectance for the material constituting the first overlay mark OM1 is increased. The first color filter 24 may include, for example, a plurality of circular or linear variable filters arranged in parallel with each other.

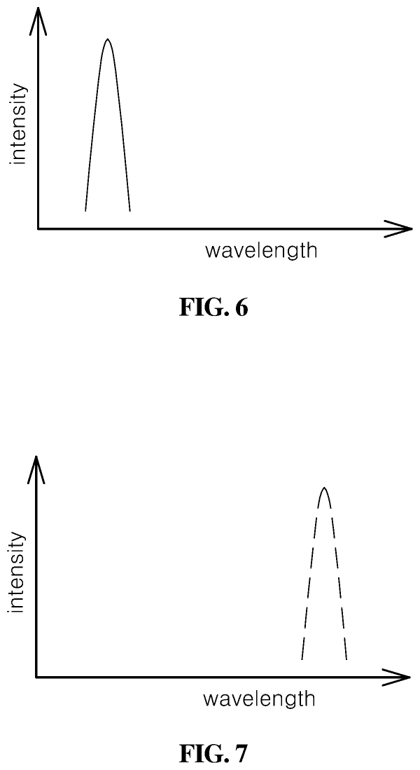

FIG. 6 is a diagram illustrating intensity for a wavelength of first illumination light passing through the first color filter shown in FIG. 5. As shown in FIG. 6, the first illumination light passing through the first color filter 24 is provided with the center wavelength being shortened and the band width being reduced.

The second color filter 25 is to adjust the center wavelength and band width of the beam reflected from the beam splitter 22 among the beams separated by the beam splitter 22 to be suitable for detecting the second overlay mark OM2 formed on the previous layer. For example, the central wavelength may be adjusted such that the transmittance of the material constituting the first overlay mark OM1 is high and the reflectance of the material constituting the overlay mark OM1 is high. The second color filter 25 may include, for example, a plurality of circular or linear variable filters arranged in parallel with each other.

The beam reflected from the beam splitter 22 has a path changed to face the second color filter 25 by a mirror 23 provided between the beam splitter 22 and the second color filter 25.

FIG. 7 is a diagram illustrating intensity for a wavelength of second illumination light passing through the second color filter shown in FIG. 5. As shown in FIG. 7, the second illumination passing through the second color filter 25 is provided with the center wavelength being increased and the band width being reduced.

The beam combiner 26 is to combine the first light and the second light. In an exemplary embodiment, the first illumination light passes through the beam combiner 26. The second illumination light is reflected from the beam combiner 26 after the path of the light is changed by the mirror 27 to face the beam combiner 26, and then combined with the first illumination light passing through the beam combiner 26.

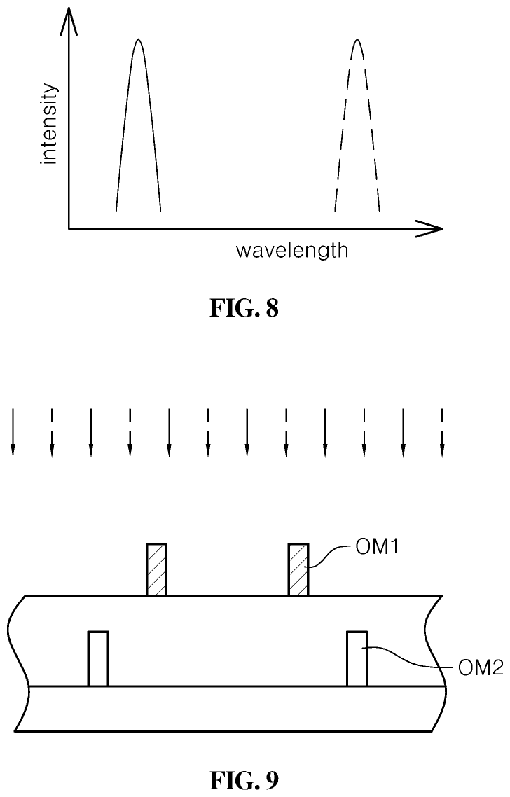

FIG. 8 is a diagram showing the intensity for the wavelength of illumination light passing through the beam combiner shown in FIG. 5. As shown in FIG. 8, the illumination light passing through the beam combiner 26 includes both the wavelength band of the first illumination light and the wavelength band of the second illumination light.

The illumination light combined by the beam combiner 26 passes through the relay lens 28 which then is reflected from the beam splitter 31 and goes towards the objective lens 32.

The objective lens 32 is to condense the light reflected from the beam splitter 31 to the measuring position of the sample S and collects the reflected beam at the measuring position. The objective lens 32 is provided on a lens focus actuator 33 for adjusting the distance between the objective lens 32 and the sample S.

As shown in FIG. 9, the first illumination light (solid line) and the second illumination light (dotted line) are both illuminated on the sample S.

The main beam splitter 30 is to split the beam collected by the objective lens 32 into two beams. The main beam splitter 30 may be a beam splitter 30 that divides incident light into two output beams which are spectrally distinct. For example, the main beam splitter 30 may include a tube beam splitter and a dichroic filter. The dichroic filter is a filter that transmits a beam of a specific wavelength. The beam collected by the objective lens 32 passes through the beam splitter 31 and the hot mirror 17, and then is split into two beams by the main beam splitter 30, including the first beam used for detecting the first overlay mark OM1 and the second beam used for detecting the second overlay mark OM2. The first beam may have substantially the same wavelength band as the first illumination light, and the second beam may have the same wavelength band as the second illumination light.

As shown in FIGS. 6 and 7, although the first illumination suitable for detecting the first overlay mark OM1 and the second illumination suitable for detecting the second overlay mark OM2 have a difference in center wavelength and a narrow band width, it may be easily separated into two beams using the dichroic filter.

The first detector 40 is to receive a first beam, which is one of the beams separated by the main beam splitter 30, to generate a first overlay mark image I1.

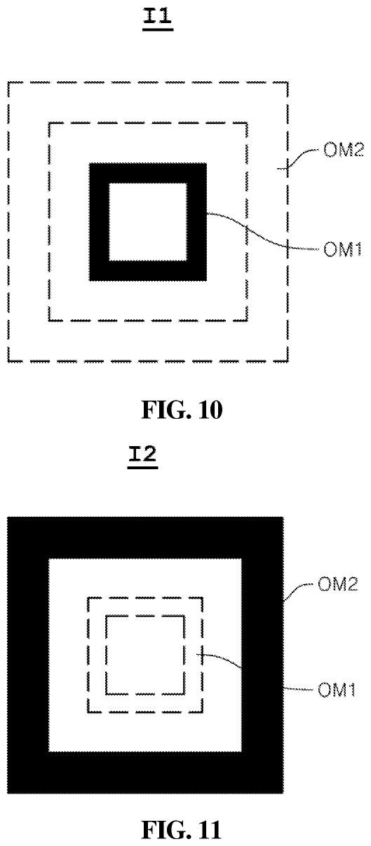

FIG. 10 is a diagram illustrating a first overlay mark image I1 acquired by the first detector shown in FIG. 5. As shown in FIG. 10, in the first overlay mark image I1 acquired by the first detector 40, the first overlay mark OM1 is displayed clearly and the second overlay mark OM2 is displayed dimly. This is because the focus is made on the first overlay mark OM1.

The second detector 50 is to receive a second beam, which is the other of the beams separated by the main beam splitter 30, to generate a second overlay mark image I2.

In an exemplary embodiment, the second detector 50 may be synchronized with the first detector 40, in order to minimize errors which may occur due to vibration during the overlay measurement process. The synchronization of the first detector 40 and the second detector 50 may be performed, for example, by generating a software synchronization signal in a detector controller 82 and transmitting the signal to the detectors 40 and 50. Herein, to avoid delay in the signal, the generated synchronization signal may be transmitted to the detectors 40 and 50 through an optical cable. The synchronization signal may also be generated from a separate external trigger source.

FIG. 11 is a diagram illustrating a second overlay mark image I2 acquired by the second detector shown in FIG. 5. As shown in FIG. 11, in the second overlay mark image I2 acquired by the second detector 33, the second overlay mark OM2 is displayed clearly, and the first overlay mark OM1 is displayed dimly, because the optical path of the second beam is adjusted so that the second overlay mark OM2 is clearly displayed by the telecentric optical system 70.

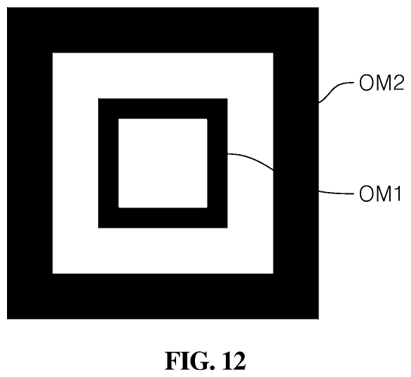

When the image of FIG. 10 and the image of FIG. 11 are combined in alignment, as shown in FIG. 12, it is possible to obtain an overlay mark image in which the first overlay mark OM1 and the second overlay mark OM2 both are clearly displayed.

The imaging optical system 60 is to allow the first beam to image on the first detector 40. As shown in FIG. 5, an imaging optical system 60 may include a tube lens 65 and a first optical filter 68. In addition, the imaging optical system 60 may further include the objective lens 32, the beam splitter 31, the hot mirror 17, and the main beam splitter 30 from other optical systems.

The objective lens 32 collects light reflected from the sample S. The light collected by the objective lens 32 is split into a first beam and a second beam by the main beam splitter 30. The first beam passing through the main beam splitter 30 is focused on the first detector 40 by the tube lens 65. Here, the focus is made on the first overlay mark. Therefore, in the first overlay mark image I1 generated by the first detector 40, the first overlay mark OM1 is displayed clearly, and the second overlay mark OM2 is displayed relatively dimly.

The first optical filter 68 is disposed in front of the first detector 40 to secondarily adjust the center wavelength and band width of the first beam for obtaining the first overlay mark image H. The first optical filter 68 may be a linear variable filter or a rotary variable filter. In an exemplary embodiment, the first optical filter 68 may also be omitted.

The telecentric imaging optical system 70 allows the second beam to image on the second detector 50 by adjusting the length of the optical path of the second beam based on the height difference Δh between the first overlay mark OM1 and the second overlay mark OM2. The telecentric imaging optical system 70 also serves to make the main ray of the second beam perpendicularly incident to the second detector 50.

The telecentric imaging optical system 70 includes an optical path adjusting unit 75, a telecentric lens 77, and a second optical filter 78.

The optical path adjusting unit 75 includes mirrors 71, 72, and 73, a mirror stage 74, and a controller 79. The mirrors 71, 72, and 73 sequentially reflect the second beam reflected from the main beam splitter 30 and enter the same into the second detector 50. In this exemplary embodiment, the optical path adjusting unit 75 includes three mirrors 71, 72 and 73 as shown in FIG. 5.

In an exemplary embodiment, the mirror stage 74 may serve to simultaneously move and to linearly move the two mirrors 71 and 72 to the right side of the drawing. When these two mirrors 71 and 72 are moved to the right in the drawing, as the distance between the main beam splitter 30 and the mirror 71 and the distance between the mirrors 72 and 73 increase, the light path becomes longer.

The controller 79 serves to adjust the moving distance of the mirror stage 74 based on the height difference Δh. The controller 79 moves the mirror stage 74 so that the entire optical path of the second beam is lengthened by considering the product of the height difference Δh and the magnification of the second overlay mark image I2, compared to the entire optical path of the first beam. The magnification of the second overlay mark image I2 means the ratio between the actual size of the second overlay mark OM2 and the size of the second overlay mark on the image. In an exemplary embodiment, the magnification of the second overlay mark image I2 may be the same as that of the first overlay mark image I1.

The telecentric lens 77 serves to make independent the distance of the optical path of the second beam and the magnification of the image. The telecentric lens 77 is a lens in which the optical axis and the main ray of the second beam may be regarded as parallel. The telecentric lens 77 may be disposed between the main beam splitter 30 and the second detector 50. For example, it may be disposed between the main beam splitter 30 and the optical path adjusting unit 75.

According to an exemplary embodiment, even when the light path of the second beam changes, the telecentric lens 77 may fix the magnification of the second overlay mark image I2. Therefore, since the moving distance of the mirror stage 74 is adjusted in proportion to the measured height difference Δh, the focus may be made without changing the magnification. In the second overlay mark image I2 generated by the second detector 50, the second overlay mark OM2 is displayed clearly, and the first overlay mark OM1 is displayed relatively dimly.

The second optical filter 78 is disposed in front of the second detector 50 to secondarily adjust the central wavelength and band width of the second beam for acquiring the second overlay mark image I2. The second optical filter 78 may be a linear variable filter or a rotary variable filter. In an exemplary embodiment, the second optical filter 78 may also be omitted.

Hereinafter, a method of measuring overlay using the above-described overlay measurement device will be described.

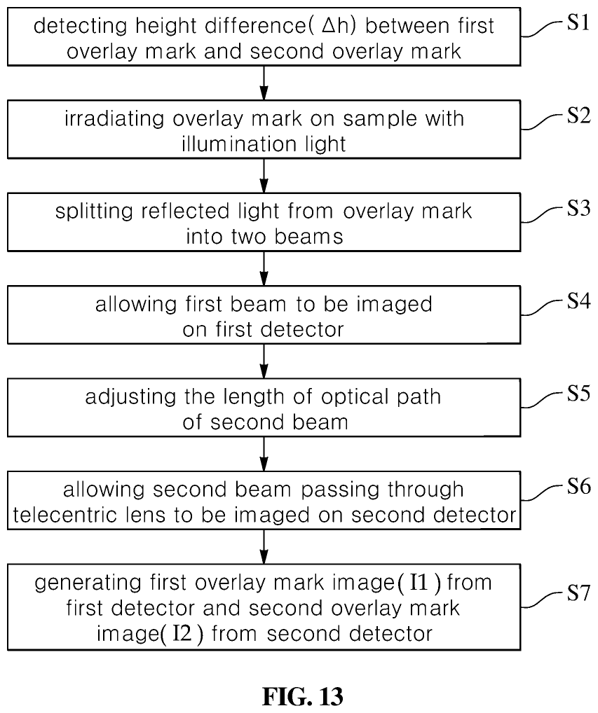

As shown in FIG. 13, the method of measuring overlay includes: detecting a height difference (Δh) between a first overlay mark and a second overlay mark (S1); irradiating the overlay mark on the sample with illumination light (S2); splitting a reflected light from the overlay mark into two beams (S3); allowing a first beam to be imaged on a first detector (S4); adjusting the length of the optical path of a second beam (S5); allowing the second beam to be imaged on a second detector, the second beam passing through a telecentric lens and an optical path of which length is adjusted (S6); generating a first overlay mark image I1 by the first detector and a second overlay mark image I2 by the second detector (S7).

In the step S1 of detecting the height difference Δh between the first overlay mark and the second overlay mark, the height difference Δh between the first overlay mark OM1 and the second overlay mark OM2 is detected using a height difference detection optical system, such as an autofocusing device using a contrast detection method or a phase difference detection method.

Next, the overlay mark on the sample is illuminated using an illumination optical system (S2).

As described above regarding FIG. 9, the illumination light may include a wavelength band suitable for acquiring the first overlay mark image I1 and a wavelength band suitable for acquiring the second overlay mark image I2.

Next, the reflected light from the overlay mark is split into two beams (S3). The first beam may be a beam of a wavelength band suitable for acquiring an image of the first overlay mark, and the second beam may be a beam of a wavelength band suitable for acquiring an image of the second overlay mark.

Next, the first beam is allowed to be imaged on the first detector (S4).

In this step, the first beam of a wavelength band suitable for acquiring an image of the first overlay mark OM1 is allowed to be imaged on the first detector 40.

Next, the length of the optical path of the second beam is adjusted (S5).

In this step, the length of the optical path of the second beam is adjusted based on the height difference Δh detected in step S1 to make focus on the second overlay mark OM2. Since the second overlay mark OM2 is formed on the lower layer, the optical path of the second beam needs to be increased.

Next, the second beam passing through the telecentric lens is allowed to be imaged on the second detector (S6).

In this step, the second beam of a wavelength band suitable for acquiring an image of the second overlay mark OM2 is allowed to be imaged on the second detector 50.

Next, a first overlay mark image I1 is generated from the first detector, and a second overlay mark image I2 is generated from the second detector (S7).

In this step, the first overlay mark image I1 in which the first overlay mark OM1 is clearly displayed is generated from the first detector.

Since the height difference between the first overlay mark OM1 and the second overlay mark OM2 is large, when the focus is made on the first overlay mark OM1 and the focus is not made on the second overlay mark OM2, the second overlay mark OM2 is dimly displayed in the first overlay mark image I1.

In addition, a second overlay mark image I2 in which the second overlay mark OM2 is clearly displayed is generated from the second detector. The first overlay mark OM1 is dimly displayed in the second overlay mark image I2.

Since the second beam passes through the telecentric lens, the magnification of the second overlay mark image I2 does not change even when the optical path of the second beam changes. Meanwhile, in the case that the telecentric lens is not used, the magnification of the second overlay mark image I2 is changed according to the change in the length of the light path, so that it is difficult to obtain an overlay mark image by combining the first overlay mark image I1 and the second overlay mark image I2.

In an exemplary embodiment, the first detector 40 and the second detector 50 may be synchronized so that the first overlay mark image I1 and the second overlay mark image I2 are generated at the same time. This is to minimize errors that may occur due to vibration during the overlay measurement process.

In addition, the overlay error is measured using the first overlay mark image I1 and the second overlay mark image I2.

While the present invention has been described with reference to exemplary embodiments, it is to be understood that the invention is not limited to the disclosed embodiments, but, on the contrary, is intended to cover various modifications and equivalent arrangements included within the spirit and scope of the appended claims. Accordingly, it should be appreciated that variations to those embodiments can be made by a person of ordinary skill in the art without departing from the scope of the invention as defined by the following claims.

1. An apparatus for measuring overlay, which is configured to measure an inter-layer overlay error in a sample with an overlay mark, the overlay mark including a first overlay mark and a second overlay mark respectively formed on different layers, the apparatus comprising:
a height difference detection optical system configured to detect a height difference between the first overlay mark and the second overlay mark;
an illumination optical system configured to irradiate the overlay mark on the sample with an illumination light;
a main beam splitter configured to split a light reflected from the overlay mark into a first beam and a second beam;
a first detector configured to receive the first beam and to generate a first overlay mark image in which a focus is made on the first overlay mark;
a second detector configured to receive the second beam and to generate a second overlay mark image in which a focus is made on the second overlay mark;
an imaging optical system configured to allow the first beam to be imaged on the first detector; and
a telecentric imaging optical system configured to include an optical path adjusting unit for adjusting a length of an optical path of the second beam based on the height difference, and a telecentric lens disposed between the main beam splitter and the second detector to allow the second beam to be imaged on the second detector.

2. The apparatus for measuring overlay of claim 1, wherein the optical path adjusting unit comprises:
at least one mirror disposed between the main beam splitter and the second detector, such that the second beam is reflected toward the second detector;
a mirror stage configured to adjust a length of the optical path of the second beam by linearly moving the at least one mirror; and
a controller configured to control the mirror stage based on the height difference.

3. The apparatus for measuring overlay of claim 2, wherein the controller controls the mirror stage so that the optical path of the second beam is lengthened in proportion to the height difference and a magnification of the second overlay mark image, and the lengthened optical path of the second beam becomes longer than an optical path of the first beam.

4. The apparatus for measuring overlay of claim 1,
wherein the imaging optical system further comprises a first optical filter which is disposed in front of the first detector to adjust a central wavelength and a band width of the first beam for obtaining the first overlay mark image; and
wherein the telecentric imaging optical system further comprises a second optical filter which is disposed in front of the second detector to adjust a central wavelength and a band width of the second beam for obtaining the second overlay mark image.

5. The apparatus for measuring overlay of claim 4, wherein the first optical filter and the second optical filter are linearly or rotationally variable.

6. The apparatus for measuring overlay of claim 1, wherein the first detector and the second detector are synchronized so that the first overlay mark image and the second overlay mark image are generated simultaneously.

7. A method of measuring overlay, which is configured to measure an inter-layer overlay error in a sample with an overlay mark, the overlay mark including a first overlay mark and a second overlay mark respectively formed on different layers, the method comprising:
detecting a height difference between the first overlay mark and the second overlay mark;
irradiating the overlay mark on the sample with an illumination light;
splitting a light reflected from the overlay mark into a first beam and a second beam;
allowing the first beam to be imaged on a first detector;
adjusting a length of an optical path of the second beam based on the height difference so that a focus is made on the second overlay mark;
allowing the second beam to be imaged on a second detector, the second beam passing through a telecentric lens and the optical path of which the length is adjusted;
generating, by the first detector, a first overlay mark image in which a focus is made on the first overlay mark; and
generating, by the second detector, a second overlay mark image in which a focus is made on the second overlay mark.

8. The method for measuring overlay of claim 7, wherein the length of the optical path of the second beam is adjusted so that the optical path of the second beam is lengthened in proportion to the height difference and a magnification of the second overlay mark image, and the lengthened optical path of the second beam becomes longer than an optical path of the first beam.

9. The method for measuring overlay of claim 7, further comprising:
adjusting a central wavelength and a band width of the first beam for acquiring the first overlay mark image; and
adjusting a central wavelength and a band width of the second beam for acquiring the second overlay mark image.

10. The method for measuring overlay of claim 9, wherein the central wavelength of the first beam and the central wavelength of the second beam are different from each other.

11. The method for measuring overlay of claim 7, wherein the first detector and the second detector are synchronized so that the first overlay mark image and the second overlay mark image are generated simultaneously.
